(19) United States
(12) Patent Application Publication
(10) Pub. No.: US 2022/0310186 A1
(43) Pub. Date: Sep. 29, 2022

(54) CHIP DETECTION METHOD AND DEVICE

(71) Applicant: CHANGXIN MEMORY TECHNOLOGIES, INC., Hefei City (CN)

(72) Inventor: Jianbo ZHOU, Hefei City (CN)

(73) Assignee: CHANGXIN MEMORY TECHNOLOGIES, INC., Hefei City (CN)

(21) Appl. No.: 17/454,620

(22) Filed: Nov. 11, 2021

Related U.S. Application Data
(63) Continuation of application No. PCT/CN2021/112035, filed on Aug. 11, 2021.

(30) Foreign Application Priority Data
Mar. 25, 2021 (CN) 202110318085.8

(51) Int. Cl. G11C 29/22; G11C 17/16; G01R 31/317

(52) U.S. Cl. CPC G11C 29/22; G11C 17/16; G01R 31/31728

(57) ABSTRACT

A chip detection method includes: providing a chip to be tested, the chip having multiple one-time programmable memories (OTPMs); transmitting a test signal to the chip to maintain the OTPMs in the chip in a latched state; and detecting whether the chip emits a low-light signal, and if yes, determining that an OTPM is leaky. The chip detection method and device can detect an OTPM that is burnt through by mistake, and can also detect an OTPM that has slight leakage, thereby preventing a defective product with a potential burn-through risk from entering a subsequent production process.

### CROSS REFERENCE TO RELATED APPLICATIONS

The present disclosure is a continuation of International Application No. PCT/CN2021/112035 filed on Aug. 11, 2021, which claims priority to Chinese Patent Application No. 202110318085.8 filed on Mar. 25, 2021. The disclosures of the above-referenced applications are incorporated herein by reference in their entirety.

### BACKGROUND

Dynamic random-access memory (DRAM) is a commonly used semiconductor structure in electronic devices such as computers. It is composed of multiple memory cells, each of which usually includes a transistor and a capacitor. In the transistor, the gate is electrically connected to a word line, the source is electrically connected to a bit line, and the drain is electrically connected to the capacitor. The word line voltage on the word line controls the on or off of the transistor, so as to read data information stored in the capacitor or write data information into the capacitor through the bit line.

### SUMMARY

The present disclosure relates to the technical field of integrated circuit (IC) failure analysis, and more specifically to a chip detection method and device.

Some embodiments of the present disclosure provide a chip detection method and device, which are aimed to solve the problem of low chip detection accuracy, so as to prevent a potentially risky defective product from entering a subsequent production process and improve the yield of a final chip product.

Some embodiments of the present disclosure provide a chip detection method, including the following steps:

providing a chip to be tested, the chip having multiple one-time programmable memories (OTPMs);

transmitting a test signal to the chip to maintain the OTPMs in the chip in a latched state; and

detecting whether the chip emits a low-light signal, and if yes, determining that an OTPM is leaky.

Some other embodiments of the present disclosure further provide a chip detection device, including:

a test module, for transmitting a test signal to a chip to be tested to maintain OTPMs in the chip in a latched state;

a detection module, for detecting a low-light signal emitted by the chip; and

a determination module, for determining whether the detection module detects a low-light signal, and if yes, determining that an OTPM is leaky.

### BRIEF DESCRIPTION OF THE DRAWINGS

FIG. 1 is a flowchart of a chip detection method according to a specific implementation of the present disclosure.

FIG. 2 is a view illustrating a chip according to a specific implementation of the present disclosure.

FIG. 3 is a view illustrating a layout for detecting the chip according to a specific implementation of the present disclosure.

FIG. 4 is a view illustrating a low-light signal detected according to a specific implementation of the present disclosure.

FIG. 5 is a block diagram of a chip detection device according to a specific implementation of the present disclosure.

### DETAILED DESCRIPTION

The specific implementations of a chip detection method and device provided by the present disclosure are described in detail below with reference to the drawings.

DRAM usually includes multiple one-time programmable memories (OTPMs), which may include electrical fuses (e-fuses), for information storage. If an OTPM leaks, various abnormalities will occur in the chip, for example, the chip may enter a 4G mode or a twin cell mode, which will affect the performance and yield of the chip. Therefore, it is very important to perform leakage detection on the OTPMs in the chip. A leakage detection method is to transmit a test instruction to all the OTPMs in the chip through a testing machine and then read the state of all the OTPMs. This leakage detection method has low accuracy. Although it can detect an OTPM with serious leakage (for example, one burnt through by mistake), it is easy to miss an OTPM with slight leakage. As a result, a defective product with a potential burn-through risk may enter a subsequent production process, resulting in waste of resources.

Various embodiments of the present disclosure can improve the chip detection accuracy so as to prevent a potentially risky defective product from entering a subsequent production process.

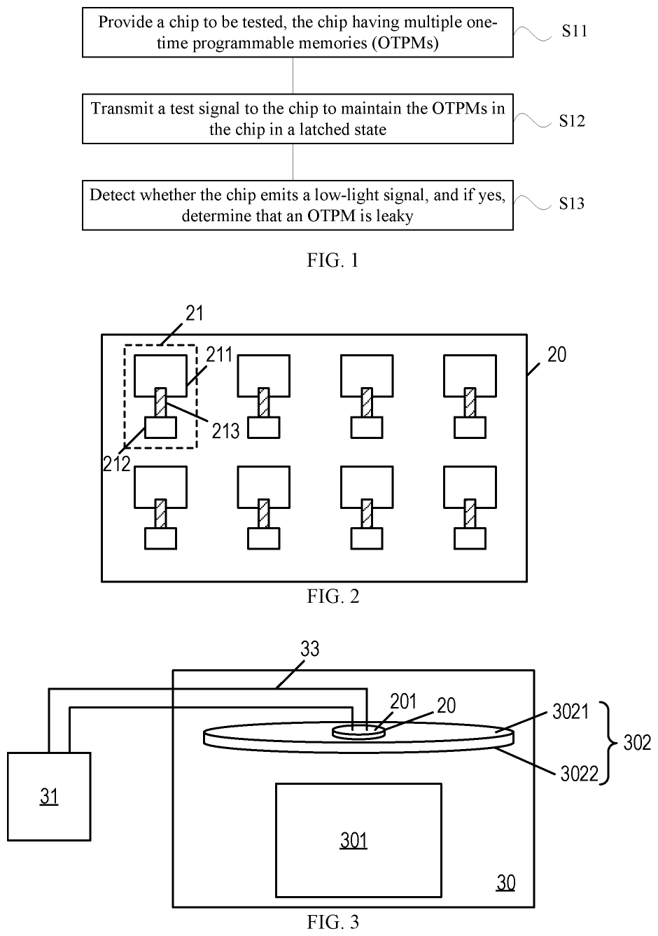

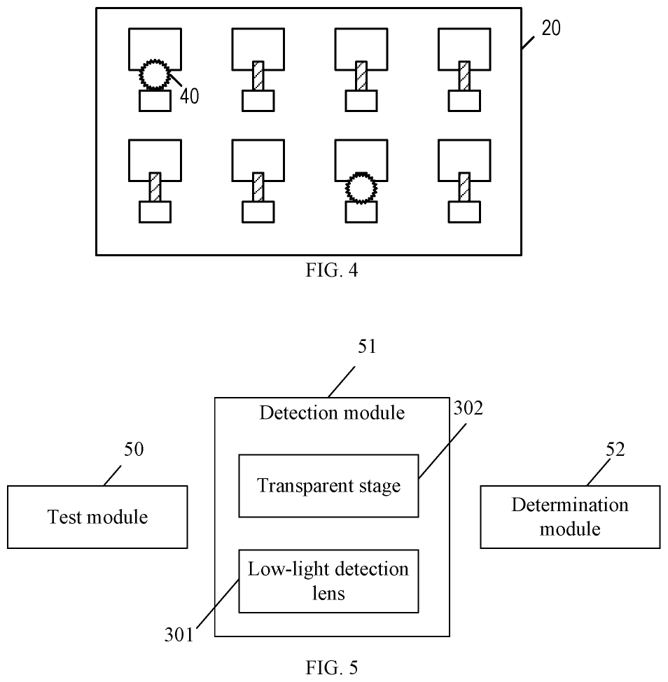

A specific implementation of the present disclosure provides a chip detection method. FIG. 1 is a flowchart of a chip detection method according to the specific implementation of the present disclosure; FIG. 2 is a view illustrating a chip according to the specific implementation of the present disclosure; FIG. 3 is a view illustrating a layout for detecting the chip according to the specific implementation of the present disclosure; and FIG. 4 is a view illustrating a low-light signal detected according to the specific implementation of the present disclosure. As shown in FIGS. 1 to 4, the chip detection method according to the specific implementation includes the following steps:

Step S11: Obtain a chip 20 to be tested, the chip 20 having multiple one-time programmable memories (OTPMs) 21, as shown in FIG. 2.

Specifically, the chip 20 may be a dynamic random-access memory (DRAM) or another chip with OTPMs 21. The chip 20 may have multiple OTPMs 21, and the multiple OTPMs 21 are arranged in an array in the chip 20, as shown in FIG. 2. The OTPMs 21 are used for information storage.

The OTPMs 21 each may have an electrical fuse (e-fuse) structure. For example, when the chip 20 is a DRAM, the OTPMs 21 having an e-fuse structure each include an active region (AR) 211, a conductive region 212 and a dielectric layer region 213 located between the AR 211 and the conductive region 212. The conductive region 212 is used to transmit a control signal to the AR 211. The AR 211, the dielectric layer region 213 and the conductive region 212 form a capacitor-like structure. The material of the conductive region 212 may be, but is not limited to, polysilicon. The material of the dielectric layer region 213 may be, but is not limited to, an oxide, such as silicon dioxide. The AR 211 includes electrical structures such as a transistor, a bit line contact portion and a capacitor contact portion. For the OTPMs 21 having an e-fuse structure, the resistance of the OTPMs 21 is adjusted by blowing a fuse (that is, the dielectric layer region 213). When the fuse is not blown, the fuse is in a high-resistance state, and the AR 211 and the conductive region 212 are in an electrically isolated state. When the fuse is blown, the fuse is in a low-resistance state, and the AR 211 and the conductive region 212 are in an electrically conductive state. By controlling the fuse to be blown or not, functions such as self-repair and mode conversion inside the chip 20 are realized. If the fuse is leaky, it will affect the electrical signal transmission between the AR 211 and the conductive region 212. Those skilled in the art may also adopt other structure for the OTPMs according to actual needs, as long as a leaky OTPM 21 is able to emit a low-light signal when it is in a differential leakage state.

Step S12: Transmit a test signal to the chip 20 to maintain the OTPMs 21 in the chip 20 in a latched state.

In some embodiments, the maintaining the OTPMs 21 in the chip 20 in a latched state specifically includes:

Repeatedly execute the following cycle steps such that the OTPMs 21 maintain a differential leakage state:

Transmit the test signal to the chip 20 to drive the chip 20 to test in a preset test mode.

Determine whether the test is completed, and if yes, execute a next cycle step.

This specific implementation does not limit the specific content of the test signal, as long as the OTPMs 21 in the chip 20 can be maintained in a latched state. For example, during the design of the chip 20, in order to meet the requirements of a subsequent performance test on the chip 20, a design for test (DFT) is set in the chip 20. The DFT includes multiple test modes. Subsequently, the chip 20 may be driven in different working modes to test various performances or multiple structures of the chip 20, so as to determine whether the chip 20 meets the design requirements or provide a reference for subsequent technical improvement of the chip. As shown in FIG. 3, in this specific implementation, the chip 20 may be placed in a detection machine 30, and the chip 20 may be electrically connected to a testing machine 31 located outside the detection machine 30 through a cable 33. The testing machine 31 transmits a test signal to the chip 20 to activate a specific test mode in the DFT, such that the chip 20 is in a preset working mode to complete a preset test program. The “multiple” mentioned in this specific implementation refers to two or more than two.

The latched state of the OTPMs 21 in the chip 20 refers to a differential leakage state of the OTPMs 21 in the chip. Specifically, a first cycle step is executed, that is, the test signal is transmitted to the chip 20 through the testing machine 31, such that the chip 20 enters a preset test mode to execute a corresponding test program. At this time, the OTPMs 21 are in a differential leakage state. For example, in the OTPMs 21, the voltage in the AR 211 is 0 V, and the voltage in the conductive region 212 is 1.2 V. Thus, in the OTPMs 21, the dielectric layer region 213 has a voltage difference. After the test program is completed, the voltage difference inside the OTPMs 21 is restored to 0 V. Then, a second cycle step is started. That is, again, the test signal is transmitted to the chip through the testing machine 31, such that the chip enters the preset test mode to execute the corresponding test program. Thus, the OTPMs 21 are again in a differential leakage state. In this way, the cycle steps are repeatedly executed such that the OTPMs 21 are always maintained in a differential leakage state. The preset test mode may be any test mode in the DFT, as long as the OTPMs 21 in the chip can be maintained in a differential leakage state.

Step S13: Detect whether the chip 20 emits a low-light signal 40, and if yes, determine that an OTPM 21 is leaky.

The low-light signal 40 is emitted by a failure region of the OTPM 21 in the latched state. A suitable low-light detection method or detection lens may be selected in advance according to a wavelength range of a low-light signal emitted by a leaky OTPM 21. Thus, a detected low-light signal 40 of the chip 20 is only emitted when an OTPM 21 leaks, thereby further improving the chip detection accuracy. Alternatively, according to a location of the OTPM 21 in the chip 20, whether a low-light signal 40 is emitted from the location of the OTPM 21 in the chip 20 is determined.

In some embodiments, the detecting whether the chip 20 emits a low-light signal includes:

Detect, from a back surface of the chip 20, whether the chip 20 emits a low-light signal.

In some embodiments, before transmitting the test signal to the chip 20, the method further includes the following step:

Place the chip 20 on a transparent stage 302 with a front surface 201 of the chip facing up, and place a low-light detection lens 301 toward a back surface 3022 of the transparent stage 302.

Specifically, the chip 20 includes a front surface 201 and a back surface that are arranged oppositely, where a surface of the chip 20 facing the transparent stage 302 is the back surface of the chip 20. The transparent stage 302 includes a front surface 3021 and a back surface 3022 that are arranged oppositely, where a surface of the transparent stage 302 facing the chip 20 is the front surface 3021 of the transparent stage. In this specific implementation, the chip 20 may be placed on the transparent stage 302 inside the detection machine 30, with the front surface of the chip facing up, and the low-light detection lens 301 for detecting a low-light signal faces the back surface of the transparent stage 302. In this way, a low-light signal emitted by the OTPM 21 in the chip 20 due to electrical leakage can be detected timely and accurately. The size of the transparent stage 302 should be much greater than that of the chip 20 so as to detect a low-light signal emitted from any location in the chip 20. The low-light signals detected by the low-light detection lens 301 directly reflects the locations of OTPMs 21 that emit low light in the chip 20 and the number of the OTPMs 21 that emit low light in the chip 20.

In some embodiments, the OTPMs 21 each include an AR 211, a conductive region 212 located outside the AR 211 and a dielectric layer region 213 located between the AR 211 and the conductive region 212. One end of the dielectric layer region 213 is connected to the AR 211, and the other end thereof is connected to the conductive region 212.

The low-light detection lens 301 is able to detect low light with a wavelength of 700-1,400 nm.

In some embodiments, the low-light detection lens 301 is an indium gallium arsenide (InGaAs) lens.

Specifically, when the dielectric layer region 213 in the OTPM 20 is in a differential leakage state, a large number of electrons and holes recombine in a local failure region in the dielectric layer region 213 that is burnt through, and the kinetic energy of the electrons is converted into light energy, thereby generating a low-light signal with a wavelength of about 1,100 nm. The InGaAs lens includes a near-infrared photodetector, which can capture a low-light signal with a wavelength of 700-1,400 nm. Therefore, the InGaAs lens can be used to capture a low-light signal emitted by a leaky OTPM 21.

Those skilled in the art may select a corresponding low-light detector according to the wavelength range of the low-light signal emitted by the OTPM 21 in the differential leakage state, so as to further improve the accuracy of the detection on the chip 20.

In some embodiments, the chip 20 has multiple OTPMs 21 arranged in an array, and the transmitting a test signal to the chip 20 specifically includes:

Transmit the test signal to the chip 20 to maintain all the OTPMs 21 in the chip 20 in a latched state.

In some embodiments, the detecting whether the chip 20 emits a low-light signal includes:

Detect whether the chip 20 emits a low-light signal, and if yes, locate an OTPM where the low-light signal appears in the chip 20.

For example, the chip 20 has 1,024 OTPMs 21 arranged in an array. When the chip 20 is detected, a test signal may be transmitted to the chip 20, such that all the OTPMs 21 in the chip 20 are maintained in a latched state. A mapping relationship between a coordinate system on an image plane detected by the low-light detection lens 301 and a coordinate system on the chip 20 is established in advance. When the low-light detection lens 301 detects a low-light signal, the location of the leaky OTPM 20 in the chip 20 is determined in a one-time, fast and accurate manner according to the mapping relationship.

The specific implementation of the present disclosure further provides a chip detection device. FIG. 5 is a block diagram of a chip detection device according to a specific implementation of the present disclosure. The chip detection device provided by the specific implementation can detect a chip by the method as shown in FIGS. 1 to 4. As shown in FIGS. 1 to 5, the chip detection device provided by the specific implementation includes:

a test module 50, for transmitting a test signal to a chip 20 to be tested to maintain OTPMs 21 in the chip 20 in a latched state;

a detection module 51, for detecting a low-light signal emitted by the chip 20; and

a determination module 52, for determining whether the detection module detects a low-light signal, and if yes, determining that an OTPM 21 is leaky.

Specifically, the test module 50 may include a testing machine 31 shown in FIG. 3, and the detection module 51 may include a detection machine 30 shown in FIG. 3.

In some embodiments, the test module 50 repeatedly executes the following cycle steps such that the OTPMs 21 maintain a differential leakage state: transmit the test signal to the chip 20 to drive the chip 20 to test in a preset test mode; and determine whether the test is completed, and if yes, execute a next cycle step.

In some embodiments, the detection module 51 is used to detect, from a back surface of the chip 20, whether the chip 20 emits a low-light signal.

In some embodiments, the detection module 51 includes a transparent stage 302 and a low-light detection lens 301. The chip 20 is placed on the transparent stage 302 with a front surface of the chip facing up, and the low-light detection lens 301 is placed toward a back surface of the transparent stage 302.

In some embodiments, the OTPMs 21 each includes an AR 211, a conductive region 212 located outside the AR 211 and a dielectric layer region 213 located between the AR 211 and the conductive region 212. One end of the dielectric layer region 213 is connected to the AR 211, and the other end thereof is connected to the conductive region 212.

The low-light detection lens 301 is able to detect low light with a wavelength of 700-1,400 nm.

In some embodiments, the low-light detection lens 301 is an InGaAs lens.

In some embodiments, the chip 20 has multiple OTPMs 21 arranged in an array.

The test module 50 is used to transmit the test signal to the chip 20 to maintain all the OTPMs 21 in the chip 20 in a latched state.

In some embodiments, the determination module 52 is used to locate an OTPM 21 where a low-light signal appears in the chip 20 after the detection module 51 detects the low-light signal emitted by the chip 20.

For example, according to the low-light signals detected by the low-light detection lens 301 in the detection module 51, the determination module 52 can quickly locate the OTPMs 21 that emit low light in the chip 20 and the number of the OTPMs 21 that emit low light in the chip 20.

In the chip detection method and device provided by the specific implementation, whether an OTPM in the chip has leakage is determined by detecting whether the chip emits a low-light signal when the OTPM is in a latched state. Embodiments of the present disclosure can detect an OTPM that is burnt through by mistake, and can also detect an OTPM that has slight leakage. In this way, embodiments of the present disclosure can prevent a defective product with a potential burn-through risk from entering a subsequent production process to waste the production resource, and can improve the yield of a final chip product.

In another implementation example, in the chip detection method and device, a test module 50, a detection module 51 and a determination module 52 are provided. The test module 50, the detection module 51 and the determination module 52 may respectively include one or more processors, controllers or chips that have a communication interface and can implement a communication protocol, and may also include a memory chip and a related interface, system transmission bus, etc., if necessary. The processors, controllers or chips execute program-related codes to implement corresponding functions. In an alternative solution, the test module 50, the detection module 51 and the determination module 52 share an integrated chip or share devices such as a processor, a controller and a memory chip. The shared processor, controller or chip executes program-related codes to implement corresponding functions.

The above described are merely preferred implementations of the present disclosure. It should be noted that several improvements and modifications may further be made by a person of ordinary skill in the art without departing from the principle of the present disclosure, and such improvements and modifications should also be deemed as falling within the protection scope of the present disclosure.

What is claimed is:

1. A chip detection method, comprising:
providing a chip to be tested, the chip having multiple one-time programmable memories (OTPMs);
transmitting a test signal to the chip to maintain the OTPMs in the chip in a latched state; and
detecting whether the chip emits a low-light signal, and if yes, determining that an OTPM is leaky.

2. The chip detection method according to claim 1, wherein the maintaining the OTPMs in the chip in a latched state comprises:
repeatedly executing the following cycle steps such that the OTPMs maintain a differential leakage state:
transmitting the test signal to the chip to drive the chip to test in a preset test mode; and
determining whether the test is completed, and if yes, executing a next cycle step.

3. The chip detection method according to claim 1, wherein the detecting whether the chip emits a low-light signal comprises:
detecting, from a back surface of the chip, whether the chip emits a low-light signal.

4. The chip detection method according to claim 3, wherein before transmitting the test signal to the chip, the method further comprises:
placing the chip on a transparent stage with a front surface of the chip facing up, and placing a low-light detection lens toward a back surface of the transparent stage.

5. The chip detection method according to claim 4, wherein the OTPMs each comprise an active region (AR), a conductive region located outside the AR and a dielectric layer region located between the AR and the conductive region; and one end of the dielectric layer region is connected to the AR, and the other end thereof is connected to the conductive region; and
the low-light detection lens is able to detect low light with a wavelength of 700-1,400 nm.

6. The chip detection method according to claim 5, wherein the low-light detection lens is an indium gallium arsenide (InGaAs) lens.

7. The chip detection method according to claim 1, wherein the chip has multiple OTPMs arranged in an array, and the transmitting a test signal to the chip comprises:
transmitting the test signal to the chip to maintain all the OTPMs in the chip in a latched state.

8. The chip detection method according to claim 7, wherein the detecting whether the chip emits a low-light signal comprises:
detecting whether the chip emits a low-light signal, and if yes, locating an OTPM where the low-light signal appears in the chip.

9. A chip detection device, comprising:
a test module configured to transmit a test signal to a chip to be tested to maintain OTPMs in the chip in a latched state;
a detection module configured to detect a low-light signal emitted by the chip; and
a determination module configured to determine whether the detection module detects a low-light signal, and if yes, determining that an OTPM is leaky.

10. The chip detection device according to claim 9, wherein the test module repeatedly executes the following cycle steps such that the OTPMs maintain a differential leakage state:
transmitting the test signal to the chip to drive the chip to test in a preset test mode; and
determining whether the test is completed, and if yes, executing a next cycle step.

11. The chip detection device according to claim 9, wherein the detection module is configured to detect, from a back surface of the chip, whether the chip emits a low-light signal.

12. The chip detection device according to claim 11, wherein the detection module comprises a transparent stage and a low-light detection lens; the chip is placed on the transparent stage with a front surface of the chip facing up; and the low-light detection lens is placed toward a back surface of the transparent stage.

13. The chip detection device according to claim 12, wherein the OTPMs each comprise an AR, a conductive region located outside the AR and a dielectric layer region located between the AR and the conductive region; and one end of the dielectric layer region is connected to the AR, and the other end thereof is connected to the conductive region; and
the low-light detection lens is able to detect low light with a wavelength of 700-1,400 nm.

14. The chip detection device according to claim 13, wherein the low-light detection lens is an InGaAs lens.

15. The chip detection device according to claim 9, wherein the chip has multiple OTPMs arranged in an array; and
the test module is used to transmit the test signal to the chip to maintain all the OTPMs in the chip in a latched state.

16. The chip detection device according to claim 15, wherein the determination module is used to locate an OTPM where a low-light signal appears in the chip after the detection module detects the low-light signal emitted by the chip.
